(19) United States
(12) Patent Application Publication
(10) Pub. No.: US 2016/0087607 A1
(43) Pub. Date: Mar. 24, 2016

(54) Bias Circuit for Comparators

(71) Applicant: QUALCOMM Incorporated, San Diego, CA (US)

(72) Inventors: Omid Rajaee, San Diego, CA (US); Wei Huang, San Diego, CA (US); Yuhua Guo, San Diego, CA (US)

(21) Appl. No.: 14/495,744

(22) Filed: Sep. 24, 2014

(51) Int. Cl. H03K 3/011; H03K 5/24

(52) U.S. Cl. CPC H03K 3/011; H03K 5/2481

(57) ABSTRACT

Pumping current into a regeneration latch of a comparator, including: a first transistor configured to receive a first constant current from a first constant current source; a first current mirror coupled to the first transistor and configured to provide a first bias current, wherein the first transistor substantially mirrors the first constant current into the first bias current in the first current mirror; a second transistor configured to receive a second constant current from a second constant current source; a second current mirror coupled to the second transistor and configured to provide a second bias current, wherein the second transistor substantially mirrors the second constant current into the second bias current in the second current mirror; and a third transistor configured to combine the first bias current and the second bias current, wherein the third transistor pumps the combined bias current into the regeneration latch.

### BACKGROUND

1. Field

This invention relates to bias circuits, and more specifically, to bias circuits that pump bias current into a regeneration latch of a comparator.

2. Background

The performance of a comparator is highly dependent on the speed of a regeneration latch which is widely used in comparators. An inverter-based regeneration latch is the most common architecture used in high-speed applications. However, the performance of the inverter-based regeneration latch depends on process, voltage, and temperature (PVT) variations. Further, in slow corners and at low supply voltages, an inverter-based latch becomes extremely slow.

### SUMMARY

In one embodiment, a bias circuit for pumping current into a regeneration latch of a comparator is disclosed. The bias circuit includes: a first transistor configured to receive a first constant current from a first constant current source: a first current mirror coupled to the first transistor and configured to provide a first bias current, wherein the first transistor substantially mirrors the first constant current into the first bias current in the first current mirror; a second transistor configured to receive a second constant current from a second constant current source; a second current mirror coupled to the second transistor and configured to provide a second bias current, wherein the second transistor substantially mirrors the second constant current into the second bias current in the second current mirror; and a third transistor configured to combine the first bias current and the second bias current, wherein the third transistor pumps the combined bias current into the regeneration latch.

In another embodiment, a latched comparator circuit is disclosed. The comparator circuit includes: a pre-amplifier stage configured to receive and amplify a pair of input signals; a regeneration latch configured to receive a combined bias current and the amplified pair of input signals, the regeneration latch operating to compare the amplified pair of input signals and output a pair of differential output signals indicating a result of the comparison; a bias circuit configured to pump the combined bias current into the regeneration latch, the bias circuit comprising: a first transistor configured to receive a first constant current from a first constant current source; a first current mirror coupled to the first transistor and configured to provide a first bias current, wherein the first transistor substantially mirrors the first constant current into the first bias current in the first current mirror; a second transistor configured to receive a second constant current from a second constant current source; a second current mirror coupled to the second transistor and configured to provide a second bias current, wherein the second transistor substantially minors the second constant current into the second bias current in the second current mirror; and a third transistor configured to combine the first bias current and the second bias current, wherein the third transistor pumps the combined bias current into the regeneration latch, wherein pumping the combined bias current into the regeneration latch increases a latch trip point which increases a mistrigger margin of the comparator.

In yet another embodiment, an apparatus for pumping current into a regeneration latch of a comparator is disclosed. The apparatus includes: means for receiving a first constant current from a first constant current source; means for providing a first bias current coupled to the means for receiving a first constant current, wherein the means for receiving a first constant current substantially mirrors the first constant current into the first bias current; means for receiving a second constant current from a second constant current source; means for providing a second bias current coupled to the means for receiving a second constant current, wherein the means for receiving a second constant current substantially mirrors the second constant current into the second bias current; and means for combining the first bias current and the second bias current, wherein the means for combining pumps the combined bias current into the regeneration latch.

Other features and advantages of the present invention should be apparent from the present description which illustrates, by way of example, aspects of the invention.

### BRIEF DESCRIPTION OF THE DRAWINGS

The details of the present invention, both as to its structure and operation, may be gleaned in part by study of the appended further drawings, in which like reference numerals refer to like parts, and in which:

FIG. 1A is a functional block diagram of a latched comparator, including a pre-amplifier stage and an inverter-based regeneration latch, in accordance with one embodiment of the present invention;

FIG. 1B is a schematic diagram of the latched comparator, including the pre-amplifier stage and the inverter-based regeneration latch, in accordance with one embodiment of the present invention;

FIG. 2A is a functional block diagram of a latched comparator, including a pre-amplifier stage and an inverter-based regeneration latch, in accordance with another embodiment of the present invention;

FIG. 2B is a schematic diagram of the latched comparator, including a pre-amplifier stage and a regeneration latch, in accordance with another embodiment of the present invention; and

FIG. 3 is a schematic diagram of a modified bias circuit in accordance with one embodiment of the present invention.

### DETAILED DESCRIPTION

To counter the problem of the regeneration latch performance being highly dependent on PVT variations, a pre-defined bias current can be supplied to the regeneration latch. Although this design reduces the speed variation over PVT, it is more prone to comparator mistriggers due to disconnection of the regeneration latch trip point to the trip point of the data latch inverter following the regeneration latch.

Several embodiments are presented for a latched comparator which tracks the PVT variations. This scheme increases the comparator bias current for fast and high voltage corners and increases the latch trip point and hence improves the mistrigger margin for these corners. It also preserves high speed properties of a conventional latch with predefined bias current and provides more robust solution in terms of speed and mistrigger margin across PVT corners. After reading this description it will become apparent how to implement the invention in various implementations and applications. Although various implementations of the present invention will be described herein, it is understood that these implementations are presented by way of example only, and not limitation. As such, this detailed description of various implementations should not be construed to limit the scope or breadth of the present invention.

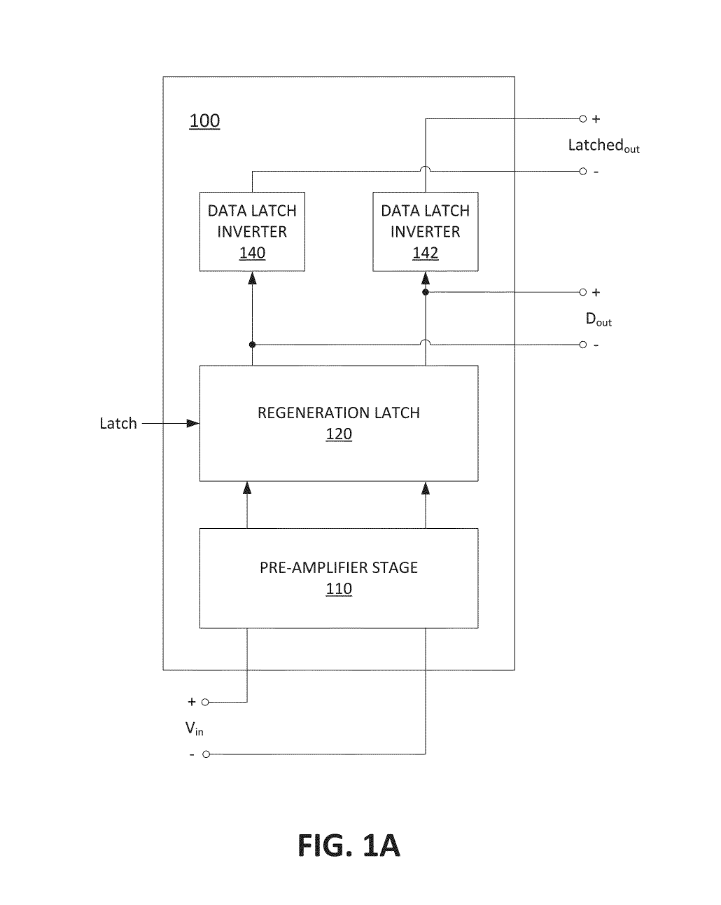

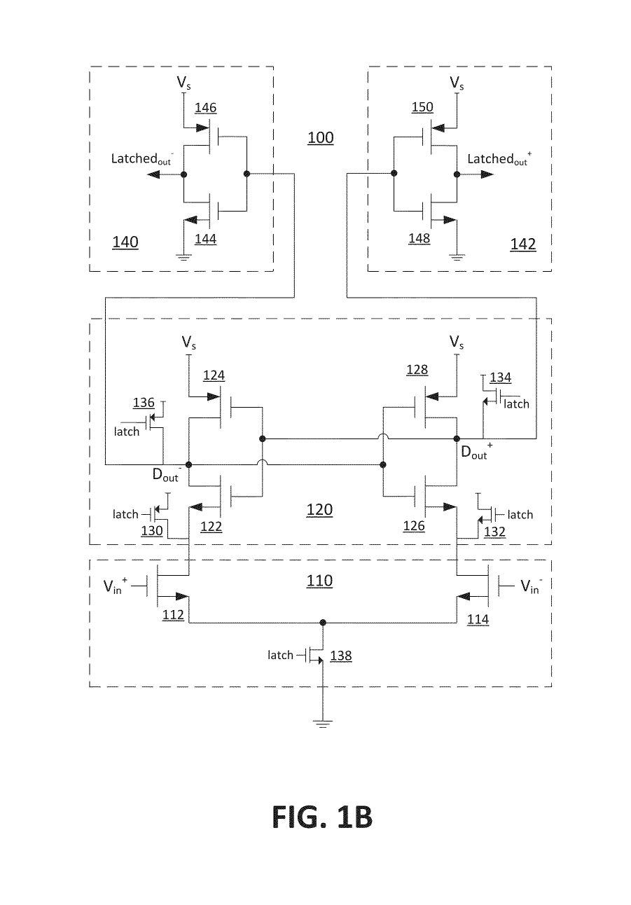

FIG. 1A is a functional block diagram of a latched comparator 100, including a pre-amplifier stage 110 and an inverter-based regeneration latch 120, in accordance with one embodiment of the present invention. The pre-amplifier stage 110 receives a pair of input signals Vᵢₙ⁺/Vᵢₙ⁻ and the regeneration latch 120 receives a latch or reset signal used to reset nodes of the regeneration latch 120. Latch signal is held low in the reset phase, and the regeneration process initiates after Latch signal transitions to high. When the regeneration process completes, one of the output nodes is at the supply voltage (Vs) and other output node is at the ground voltage. The latched comparator 100 also includes data latch inverters 142 and 140 coupled to output nodes outputting differential signals Dₒᵤₜ⁺ and Dₒᵤₜ⁻, respectively. Further, the data latch inverters 142 and 140 output Latchedₒᵤₜ⁺ and Latchedₒᵤₜ⁻ signals, respectively.

FIG. 1B is a schematic diagram of the latched comparator 100, including the pre-amplifier stage 110 and the inverter-based regeneration latch 120, in accordance with one embodiment of the present invention. The pre-amplifier stage 110 includes a differential pair of transistors 112, 114 configured to receive a pair of input signals Vᵢₙ⁺/Vᵢₙ⁻ at the gate terminals of the transistors 112, 114, respectively. The regeneration latch 120 includes a pair of cross-coupled inverters 122, 124 and 126, 128. The first inverter 122, 124 includes n-type metaloxide semiconductor field-effect (NMOS) transistor 122 and p-type MOS (PMOS) transistor 124. The gate terminals of transistors 122, 124 are coupled together, while the drain terminals of transistors 122, 124 are also coupled together and to output terminal. Dₒᵤₜ⁻. The source terminal of NMOS transistor 122 is coupled to the drain terminal of NMOS transistor 112, while the source terminal of PMOS transistor 124 is coupled to the supply voltage. The second inverter 126,128 includes NMOS transistor 126 and PMOS transistor 128. The gate terminals of transistors 126,128 are coupled together, while the drain terminals of transistors 126,128 are also coupled together and to output terminal, Dₒᵤₜ⁺. The source terminal of NMOS transistor 126 is coupled to the drain terminal of NMOS transistor 114, while the source terminal of PMOS transistor 128 is coupled to the supply voltage. Further, the cross coupling between the inverters occurs with the gate terminals of transistors 122, 124 in the first inverter coupling to the drain terminals of transistors 126, 128 in the second inverter. The cross coupling also occurs with the gate terminals of transistors 126, 128 in the second inverter coupling to the drain terminals of transistors 122, 124 in the first inverter.

The latched comparator 100 also includes data latch inverters 142 and 140 coupled to output nodes outputting signals, Dₒᵤₜ⁺ and Dₒᵤₜ⁻, and respectively. The data latch inverter 140 includes NMOS transistor 144 and PMOS transistor 146. The gate terminals of transistors 144, 146 are coupled together and to terminal Dₒᵤₜ⁻, while the drain terminals of transistors 144,146 are also coupled together and to output terminal, Latchedₒᵤₜ⁻. The source terminal of NMOS transistor 144 is coupled to the ground voltage, while the source terminal of PMOS transistor 146 is coupled to the supply voltage. The data latch inverter 142 includes NMOS transistor 148 and PMOS transistor 150. The gate terminals of transistors 148, 150 are coupled together and to terminal Dₒᵤₜ⁺, while the drain terminals of transistors 148, 150 are also coupled together and to output terminal, Latchedₒᵤₜ⁺. The source terminal of NMOS transistor 148 is coupled to the ground voltage, while the source terminal of PMOS transistor 150 is coupled to the supply voltage.

In the reset phase of the latched comparator 100, Latch signal is held low. Thus, in the reset phase, transistors 134, 136 reset the output nodes Dₒᵤₜ⁺ and Dₒᵤₜ⁻, respectively, and transistors 130, 132 reset the drain terminals of a differential pair of transistors 112, 114, respectively (which are coupled to the source terminals of transistors 122, 128, respectively), to the supply voltage Vₛ. In the reset phase with Latch signal at low, transistor 138 is turned off and no supply current is flowing in the differential pair of transistors 112, 114.

In the regeneration phase of the latched comparator 100, Latch signal is held high. Thus, in the regeneration phase, reset transistors 130, 132, 134, 136 are turned off and transistor 138 is turned on. The current starts flowing in transistor 138 and in the differential pair of transistors 112, 114. When the regeneration process begins, one of the cross-coupled inverters 122, 124 or 126, 128 receives more current, depending on the input voltages (Vᵢₙ⁺/Vᵢₙ⁻), and determines the final state of output signal, Dₒᵤₜ⁺ and Dₒᵤₜ⁻. When the regeneration process completes, one of the output nodes is at the supply voltage (Vs) and other output node is at the ground voltage. In the illustrated embodiment of FIG. 1B, reset transistors 130, 132, 134, 136 are PMOS transistors and transistor 138 is an NMOS transistor.

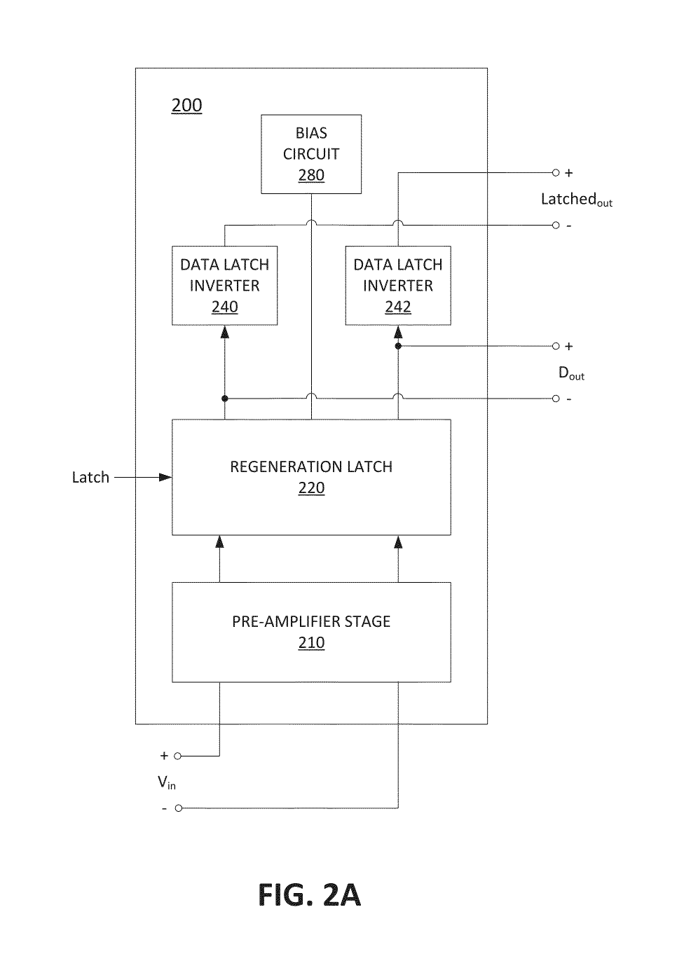

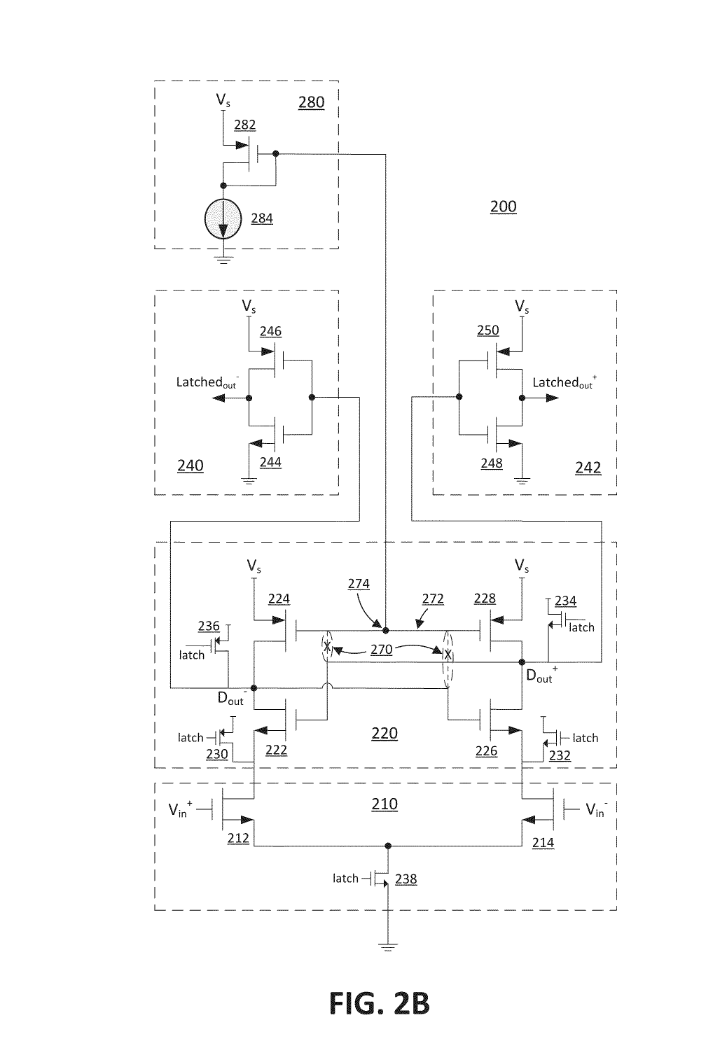

In one embodiment, a pre-defined bias current can be supplied to the regeneration latch 120 of FIG. 1A to counter the problem of the regeneration latch performance being highly dependent on PVT variations. FIG. 2A is a fimetional block diagram of a latched comparator 200, including a pre-amplifier stage 210 and an inverter-based regeneration latch 220, in accordance with another embodiment of the present invention. As with FIG. 1A, the pre-amplifier stage 210 receives input signal Vᵢₙ⁺/Vᵢₙ⁻ and the regeneration latch 220 receives a latch or reset signal used to reset certain nodes of the regeneration latch 220. The latched comparator 200 also includes data latch inverters 242 and 240 coupled to output nodes outputting signals, Dₒᵤₜ⁺ and Dₒᵤₜ⁻, respectively. Further, the data latch inverters 242 and 240 output Latchedₒᵤₜ⁺ and Latchedₒᵤₜ⁻ signals, respectively. The latched comparator 200 of FIG. 2A further includes a bias circuit 280 to supply a pre-defined bias current to the regeneration latch 220.

FIG. 2B is a schematic diagram of the latched comparator 200, including a pre-amplifier stage 210 and a regeneration latch 220, in accordance with another embodiment of the present invention. The latched comparator 200 also includes a current bias circuit 280 to supply a pre-defined bias current to the regeneration latch 220. Again, the pre-amplifier stage 210 includes a differential pair of transistors 212,214 configured to receive a pair of input signals Vᵢₙ⁺/Vᵢₙ⁻ at gate terminals of the transistors 212, 214, respectively. The regeneration latch 220 includes a pair of cross-coupled transistors 222, 226 and a pair of gate-coupled transistors 224, 228. In the illustrated embodiment of FIG. 2B, the pair of cross-coupled transistors includes NMOS transistor 222 and NMOS transistor 226, while the pair of gate-coupled transistors includes PMOS transistor 224 and PMOS transistor 228. The drain terminals of transistors 222, 224 are also coupled together and to output terminal, Dₒᵤₜ⁻. The source terminal of NMOS transistor 222 is coupled to the drain terminal of NMOS transistor 212, while the source terminal of PMOS transistor 224 is coupled to the supply voltage. The drain terminals of transistors 226, 228 are also coupled together and to output terminal, Dₒᵤₜ⁺. The source terminal of NMOS transistor 226 is coupled to the drain terminal of NMOS transistor 214, while the source terminal of PMOS transistor 228 is coupled to the supply voltage. Further, the cross coupling between the transistors occurs with the gate terminal of transistor 222 coupling to the drain terminal of transistor 226. The cross coupling also occurs with the gate terminal of transistor 226 coupling to the drain terminal of transistor 222.

The latched comparator 200 also includes data latch inverters 242 and 240 coupled to output nodes outputting signals, and Dₒᵤₜ⁺ and Dₒᵤₜ⁻, respectively. The data latch inverter 240 includes NMOS transistor 244 and PMOS transistor 246. The gate terminals of transistors 244, 246 are coupled together and to terminal Dₒᵤₜ⁻, while the drain terminals of transistors 244,246 are also coupled together and to output terminal, Latchedₒᵤₜ⁻. The source terminal of NMOS transistor 244 is coupled to the ground voltage, while the source terminal of PMOS transistor 246 is coupled to the supply voltage. The data latch inverter 242 includes NMOS transistor 248 and PMOS transistor 250, The gate terminals of transistors 248, 250 are coupled together and to terminal Dₒᵤₜ⁺, while the drain terminals of transistors 248, 250 are also coupled together and to output terminal, Latchedₒᵤₜ⁺. The source terminal of NMOS transistor 248 is coupled to the ground voltage, while the source terminal of PMOS transistor 250 is coupled to the supply voltage.

Unlike the regeneration latch 120 of FIG. 1B, the regeneration latch 220 of FIG. 2B is configured so that the gate terminals of transistors 222, 224 are not coupled together, and the gate terminals of transistors 226, 228 are also not coupled together. That is, the connections between the gate terminals have been disconnected as shown in 270. The disconnection 270 is made to decouple the PVT variations from the regeneration latch performance by configuring the regeneration latch 220 so that the trip point of the regeneration latch 220 does not track the trip point of the inverters 240, 242 following the latch 220. Further, the gate terminals of transistors 224, 228 are coupled (see 272) to each other to form a pair of gate-coupled transistors. Although this configuration reduces the speed variation over PVT, it is more prone to comparator mistriggers due to disconnection 270 of the regeneration latch trip point to the trip point of the data latch inverters 240, 242 following the regeneration latch 220.

To substantially reduce the comparator mistriggers, the latch comparator 200 incorporates a current bias circuit 280 including transistor 282 and a constant current source 284 to inject a pre-defined bias current to the common gate terminal 274 of transistors 224, 228 in the regeneration latch 220. In the illustrated embodiment of FIG. 2B, a bias current is provided by the current source 284 to the common gate terminal 274 by, for example, substantially mirroring the current flowing from the constant current source 284 through PMOS transistor 282. In FIG. 2B, the gate terminal and the drain terminal of transistor 282 are coupled together.

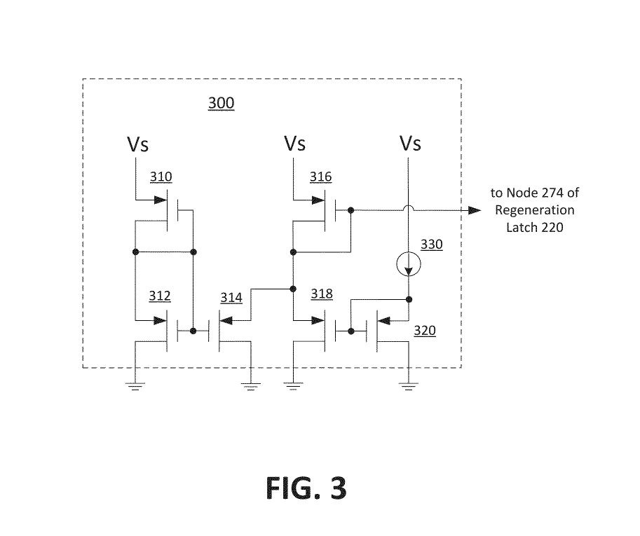

FIG. 3 is a schematic diagram of a modified bias circuit 300 in accordance with one embodiment of the present invention. The modified bias circuit 300 pumps more comparator bias current into the regeneration latch 220 for fast corners and high supply voltage and increases the latch trip point which consequently increases the mistrigger margin. In the illustrated embodiment of FIG. 3, the modified bias circuit 300 includes transistor 316 which injects a bias current to the regeneration latch 220, similar to transistor 282 in the bias circuit 280 of FIG. 2B. A first bias current is provided by the current source 330 and flows through transistor 320. A second bias current is provided by the supply voltage and flows through transistor s 310 and 312. A pair of current mirrors 312, 314 and 318, 320 is configured to minor the current flowing through transistors 310/312 and 320. The first current mirror configured with transistors 312, 314 mirrors the current flowing through transistors 310/312, while the second current mirror configured with transistors 318, 320 mirrors the current flowing through transistor 320. The first and second bias currents are then combined by transistor 316 and provided to the regeneration latch 220. Accordingly, current source 330 and transistors 310, 312, 314, 316, 318, 320 are configured to pump more current into the regeneration latch 220 and to increase the trip point of the regeneration latch 220. This increases the mistrigger margin at high supply voltages, high temperatures and/or fast corners.

In the illustrated embodiment of FIG. 3, all transistors 310, 312, 314, 316, 318, 320 are configured as PMOS transistors. The gate and drain terminals of transistor 310 are coupled together and are also coupled with gate and source terminals of transistor 312. The gate terminals of transistors 312, 314 are coupled together. The source terminals of transistors 314, 318 are coupled together and are also coupled with gate and drain terminals of transistor 316. The gate terminals of transistors 318, 320 are coupled together and are also coupled to the source terminal of transistor 320, which is connected to one node of the current source 330. The other node of the current source 330 is connected to the supply voltage. The source terminals of transistors 310, 316 are also connected to the supply voltage, while the drain terminals of transistors 312, 314, 318, 320 are connected to the ground voltage.

Although several embodiments of the invention are described above, many variations of the invention are possible. For example, although the current bias circuit is configured to use a current mirror circuit, other techniques or configurations can be used to perform the same or similar function. Further, the constant current source in the bias circuit can be implemented using, for example, a voltage source in series with a resistor, a transistor-based active current source, a current mirror, another current source circuit, or any combination thereof. Features of the various embodiments may be combined in combinations that differ from those described above. Moreover, for clear and brief description, many descriptions of the systems and methods have been simplified. Many descriptions use terminology and structures of specific standards. However, the disclosed systems and methods are more broadly applicable.

Those of skill will appreciate that the various illustrative blocks and modules described in connection with the embodiments disclosed herein can be implemented in various forms. Some blocks and modules have been described above generally in terms of their functionality. How such functionality is implemented depends upon the design constraints imposed on an overall system. Skilled persons can implement the described functionality in varying ways for each particular application, but such implementation decisions should not be interpreted as causing a departure from the scope of the invention. In addition, the grouping of functions within a module, block, or step is for ease of description. Specific functions or steps can be moved from one module or block without departing from the invention.

The various illustrative logical blocks, units, steps, components, and modules described in connection with the embodiments disclosed herein can be implemented or performed with a processor, such as a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor can be a microprocessor, but in the alternative, the processor can be any processor, controller, microcontroller, or state machine. A processor can also be implemented as a combination of computing devices, for example, a combination of a DSP and a microprocessor, a plurality of microprocessors, one or more microprocessors in conjunction with a DSP core, or any other such configuration. Further, circuits implementing the embodiments and functional blocks and modules described herein can be realized using various transistor types, logic families, and design methodologies.

The above description of the disclosed embodiments is provided to enable any person skilled in the art to make or use the invention. Various modifications to these embodiments will be readily apparent to those skilled in the art, and the generic principles described herein can be applied to other embodiments without departing from the spirit or scope of the invention. Thus, it is to be understood that the description and drawings presented herein represent presently preferred embodiments of the invention and are therefore representative of the subject matter which is broadly contemplated by the present invention. It is further understood that the scope of the present invention fully encompasses other embodiments that may become obvious to those skilled in the art and that the scope of the present invention is accordingly limited by nothing other than the appended claims.

What is claimed is:

1. A bias circuit for pumping current into a regeneration latch of a comparator, the bias circuit comprising:
a first transistor configured to receive a first constant current from a first constant current source;
a first current mirror coupled to the first transistor and configured to provide a first bias current, wherein the first transistor substantially mirrors the first constant current into the first bias current in the first current mirror;
a second transistor configured to receive a second constant current from a second constant current source;
a second current mirror coupled to the second transistor and configured to provide a second bias current, wherein the second transistor substantially mirrors the second constant current into the second bias current in the second current mirror; and
a third transistor configured to combine the first bias current and the second bias current, wherein the third transistor pumps the combined bias current into the regeneration latch.

2. The bias circuit of claim 1, wherein a gate terminal of the first transistor is coupled to a source terminal of the first transistor.

3. The bias circuit of claim 1, wherein the first current mirror comprises
a fourth transistor having a gate terminal coupled to a gate terminal of the first transistor to mirror the first constant current into the first bias current.

4. The bias circuit of claim 1, wherein gate and drain terminals of the third transistor are coupled together to a source terminal of a fourth transistor.

5. The bias circuit of claim 1, wherein the first constant current source is a current source having first and second nodes, the first node coupled to the source terminal of the first transistor and the second node coupled to a supply voltage.

6. The bias circuit of claim 1, wherein a gate terminal of the second transistor is coupled to a source terminal of the second transistor.

7. The bias circuit of claim 1, wherein the second current mirror comprises
a fifth transistor having a gate terminal coupled to a gate terminal of the second transistor to mirror the second constant current into the second bias current.

8. The bias circuit of claim 1, wherein gate and drain terminals of the third transistor are coupled together to a source terminal of a fifth transistor.

9. The bias circuit of claim 1, wherein the second constant current source is a sixth transistor with gate and drain terminals coupled together and a source terminal coupled to a supply voltage.

10. A latched comparator circuit, comprising:
a pre-amplifier stage configured to receive and amplify a pair of input signals;
a regeneration latch configured lo receive a combined bias current and the amplified pair of input signals, the regeneration latch operating to compare the amplified pair of input signals and output a pair of differential output signals indicating a result of the comparison;
a bias circuit configured to pump the combined bias current to the regeneration latch, the bias circuit comprising:
a first transistor configured to receive a first constant current from a first constant current source;
a first current mirror coupled to the first transistor and configured to provide a first bias current, wherein the first transistor substantially mirrors the first constant current into the first bias current in the first current mirror;
a second transistor configured to receive a second constant current from a second constant current source;
a second current mirror coupled to the second transistor and configured to provide a second bias current, wherein the second transistor substantially mirrors the second constant current into the second bias current in the second current mirror; and
a third transistor configured to combine the first bias current and the second bias current, wherein the third transistor pumps the combined bias current into the regeneration latch,
wherein pumping the combined bias current into the regeneration latch increases a latch trip point which increases a mistrigger margin of the comparator.

11. The latched comparator circuit of claim 10, wherein a gate terminal of first transistor is coupled to a source terminal of the first transistor.

12. The latched comparator circuit of claim 10, wherein the first current mirror comprises
a fourth transistor having agate terminal coupled to a gate terminal of the first transistor to mirror the first constant current into the first bias current.

13. The latched comparator circuit of claim 10, wherein gate and drain terminals of the third transistor are coupled together to a source terminal of a fourth transistor.

14. The latched comparator circuit of claim 10, wherein the first constant current source is a current source having first and second nodes, the first node coupled to the source terminal of the first transistor and the second node coupled to a supply voltage.

15. The latched comparator circuit of claim 10, wherein a gate terminal of the second transistor is coupled to a source terminal of the second transistor.

16. The latched comparator circuit of claim 10, wherein the second current mirror comprises
a fifth transistor having a gate terminal coupled to a gate terminal of the second transistor to mirror the second constant current into the second bias current.

17. The latched comparator circuit of claim 10, wherein gate and drain terminals of the third transistor are coupled together to a source terminal of a fifth transistor.

18. The latched comparator circuit of claim 10, wherein the second constant current source is a sixth transistor with gate and drain terminals coupled together and a source terminal coupled to a supply voltage.

19. An apparatus for pumping current into a regeneration latch of a comparator, the apparatus comprising:
means for receiving a first constant current from a first constant current source;
means for providing a first bias current coupled to the means for receiving a first constant current, wherein the means for receiving a first constant current substantially mirrors the first constant current into the first bias current;
means for receiving a second constant current from a second constant current source;
means for providing a second bias current coupled to the means for receiving a second constant current, wherein the means for receiving a second constant current substantially mirrors the second constant current into the second bias current; and
means for combining the first bias current and the second bias current, wherein the means for combining pumps the combined bias current into the regeneration latch.
